(19) United States
(12) Patent Application Publication
(10) Pub. No.: US 2011/0210652 A1
(43) Pub. Date: Sep. 1, 2011

(54) DISTRIBUTION CABINET FOR COMMUNICATIONS AND DATA TECHNOLOGY

(75) Inventors: Oliver Birkenstock, Berlin (DE); Adrian Benedetto, Berlin (DE); Bernd Delakowitz, Berlin (DE); Wolfgang Kraft, Berlin (DE)

(73) Assignee: ADC GmgH, Berlin (DE)

(21) Appl. No.: 13/127,949

(22) PCT Filed: Oct. 27, 2009
(86) PCT No.: PCT/EP2009/007666

§ 371 Date: May 5, 2011

(30) Foreign Application Priority Data
Nov. 5, 2008 (DE) 10 2008 056062.6

(51) Int. Cl. H05K 7/20; H02B 1/56

(52) U.S. Cl. 312/236

(57) ABSTRACT

The invention relates to a distribution cabinet (1) for communications and data technology, comprising a rack (2), at least one roof module (30), side walls (32), at least one rear wall (31) and at least one door (33) being fastened on the rack (2), the rack (2) having vertical struts (3) and lower and upper horizontal struts (8-11, 4-7), the roof module (30) being fastened on the upper horizontal struts (4-7), at least one side wall, a rear wall and/or a door being in the form of a double wall (31-33), an air flow being capable of flowing in the double wall (31-33), which air flow is flow-connected to an air flow in the roof module (30), wherein the upper horizontal strut (4-7) on which the double wall (31-33) is fastened has a cross section in terms of flow technology which allows for an at least partial horizontal air flow from the double wall (31-33) and an at least partial vertical air flow to at least one opening (30a) in the roof module (30), the opening (30a) in the roof module (30) being arranged so as to be offset inward with respect to the opening (34) of the double wall.

The invention relates to a distribution cabinet for communications and data technology.

Distribution cabinets for communications and data technology generally comprise a rack, at least one roof module, side walls, at least one rear wall and at least one door being fastened on the rack. In this case, the rack has vertical struts and lower and upper horizontal struts. It is further known for the side walls, rear walls and/or doors to be in the form of a double wall, with the result that an air flow can flow in the double wall, which air flow is flow-connected to an air flow in the roof module. As a result of convection, the air which is being heated in the double wall can then flow upward into the roof module and can be dissipated to the outside, with it being possible for cold air to flow in its wake. The transition from the double wall to the roof module in this case takes place vertically, i.e. in the region of the air channel of the double wall the roof module has corresponding openings. In this case there is the problem of sealtightness since the double wall and the roof module should be fastened in such a way that the ingress of moisture or dust at the join is not possible, which is made more difficult by the air flow opening.

The invention is based on the technical problem of providing a distribution cabinet for telecommunications and data technology which has improved sealtightness.

The solution to the technical problem results from the subject matter having the features of claim 1. Further advantageous configurations of the invention result from the dependent claims.

In this regard, the distribution cabinet comprises a rack, at least one roof module, side walls, at least one rear wall and at least one door being fastened on the rack, the rack having vertical struts and lower and upper horizontal struts, the roof module being fastened on the upper horizontal struts, at least one side wall, a rear wall and/or a door being in the form of a double wall, an air flow being capable of flowing in the double wall, which air flow is flow-connected to an air flow in the roof module, the upper horizontal strut on which the double wall is fastened having a cross section in terms of flow technology which allows for an at least partial horizontal air flow from the double wall and an at least partial vertical air flow to at least one opening in the roof module, the opening in the roof module being arranged so as to be offset inward with respect to the opening of the double wall. As a result, openings of the roof module in the fastening region of the double wall are no longer required. Instead, the openings in the roof module can be shifted further inward, with the result that the regions for the fastening and air guidance are separated from one another. The basic concept is in this case to use parts of the frame construction as a channel for cooling media, in particular air. Preferably, the strut is in this case formed in such a way that the air flow takes place from the double wall horizontally into the strut and from there vertically into the roof module. Further preferably, all of the upper horizontal struts are designed to have cross sections in terms of flow technology and, correspondingly, both the side wall, door and rear wall are formed as a double wall.

In a further preferred embodiment, the upper horizontal strut has openings, which are aligned toward the double wall and toward the roof module and correspond to the openings in the double wall and the roof module.

In a further preferred embodiment, the horizontal struts have a parallelepipedal basic shape, a baffle set at an angle being arranged within the strut, by means of which the deflection from the horizontal air flow into the strut to the vertical air flow into the roof module is improved.

In a further preferred embodiment, the upper horizontal strut(s) is/are formed with two parts.

In a further preferred embodiment, the outer or the inner wall of the double wall is designed to have ventilation slots, which are preferably arranged in the base region. The embodiment with the slots on the outer wall preferably involves passive cooling, i.e. the air flows by means of convection past the inner wall of the double wall and absorbs heat from the interior of the cabinet. The heated air then flows through the strut into the roof module and the heat is dissipated to the outside. The embodiment with the ventilation slots on the inner wall involves active cooling. In this case, cold air is blown into the strut and from there into the double wall by means of an air-conditioning module in the roof module, the cold air passing through the ventilation slots at the bottom into the interior of the distribution cabinet and from there, by means of convection, upwards back into the roof module.

In a further preferred embodiment, an intermediate wall is arranged between the outer and inner wall of the double wall, both the outer wall and the inner wall of the double wall being designed to have ventilation slots, with the result that active and passive cooling can be combined with one another.

In a further preferred embodiment, the intermediate wall is in the form of a heat exchanger, with the result that, in addition, heat transfer from the inner channel to the outer channel can take place.

The invention will be explained in more detail below with reference to a preferred exemplary embodiment. In the figures:

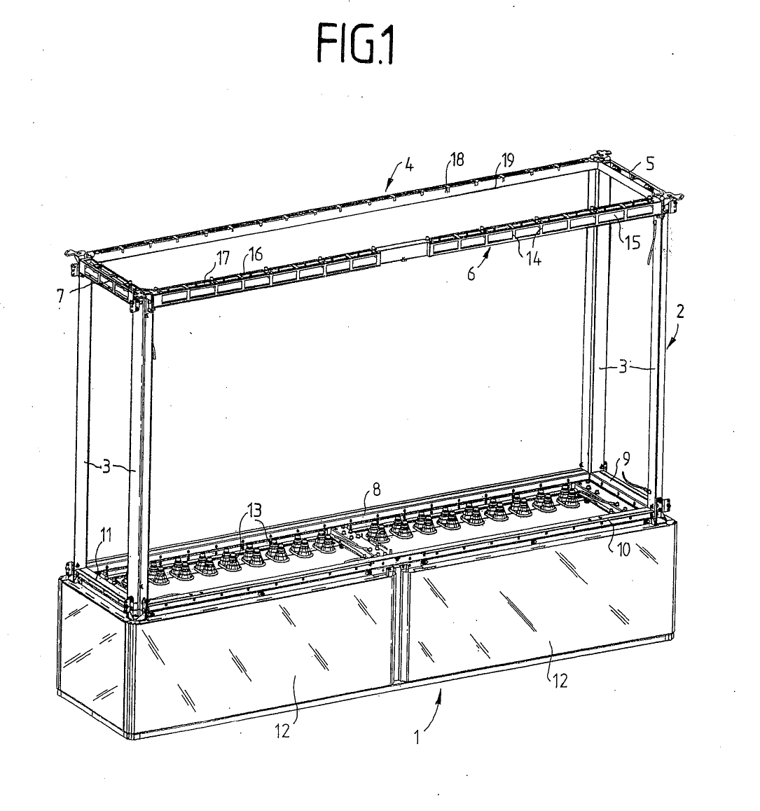

FIG. 1 shows a perspective illustration of a distribution cabinet without doors, side walls, rear wall and roof module,

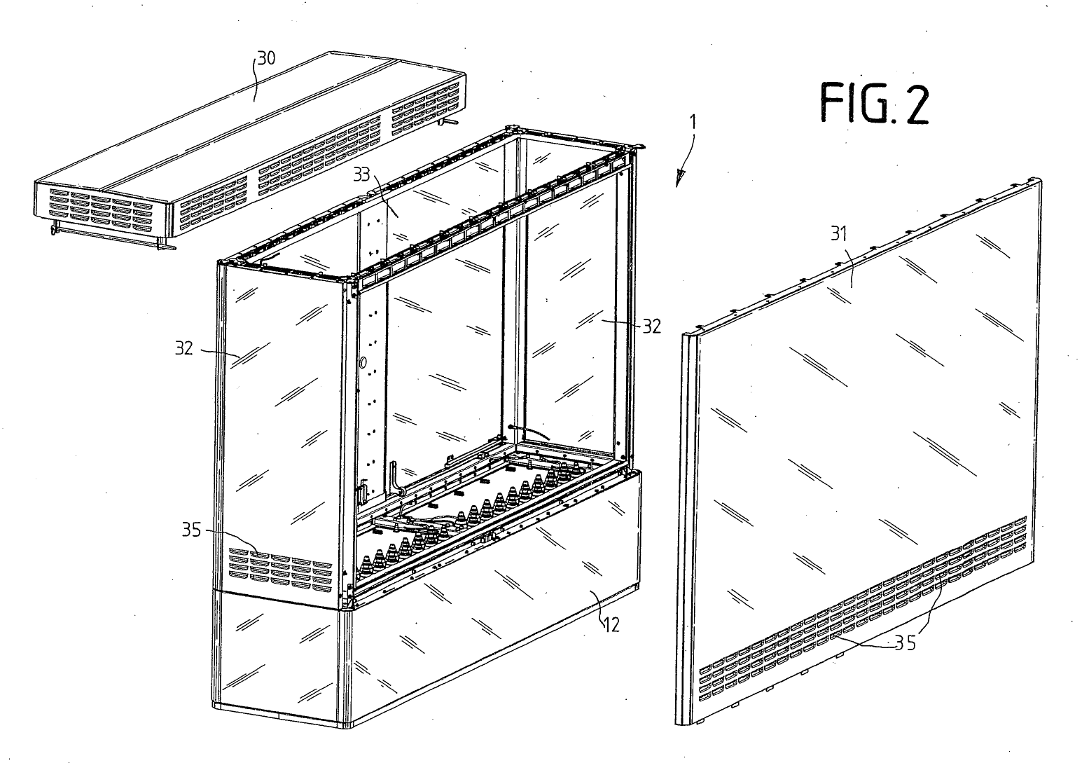

FIG. 2 shows a perspective illustration from the rear of a distribution cabinet with a roof module and rear wall which have been lifted off,

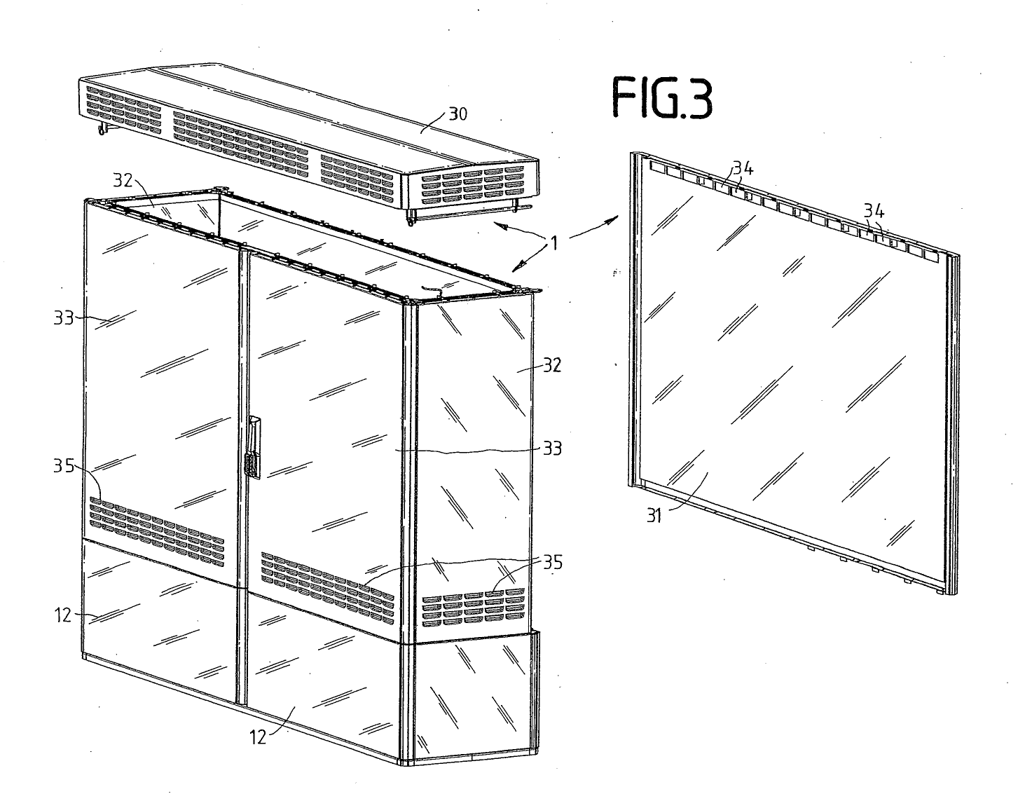

FIG. 3 shows a perspective illustration from the front of the illustration of the distribution cabinet shown in FIG. 2,

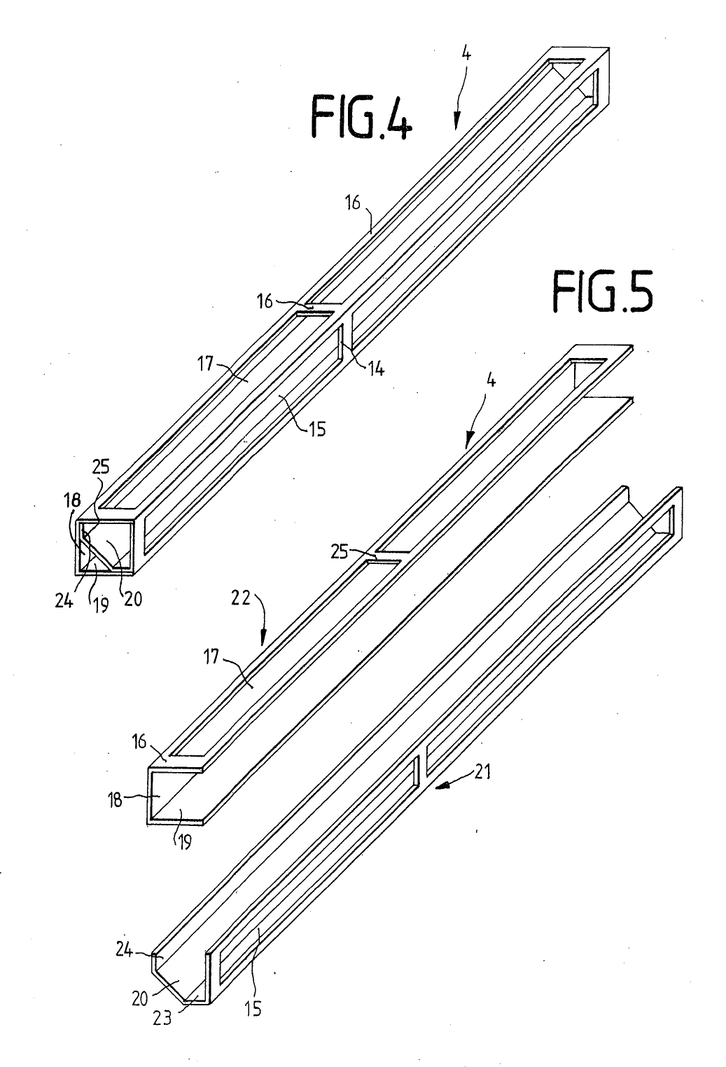

FIG. 4 shows a perspective illustration of an upper horizontal strut,

FIG. 5 shows an exploded illustration of the upper horizontal strut,

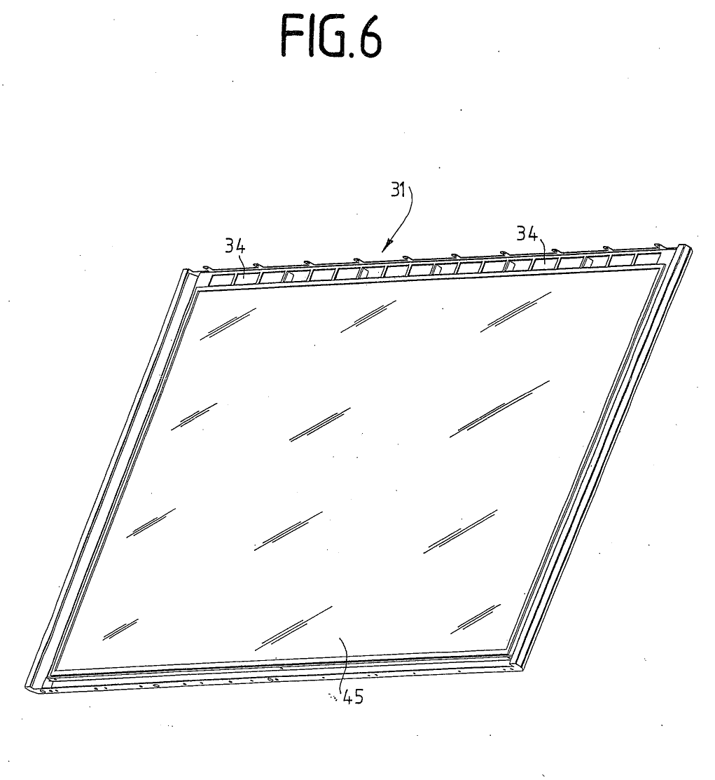

FIG. 6 shows a perspective illustration of a rear wall,

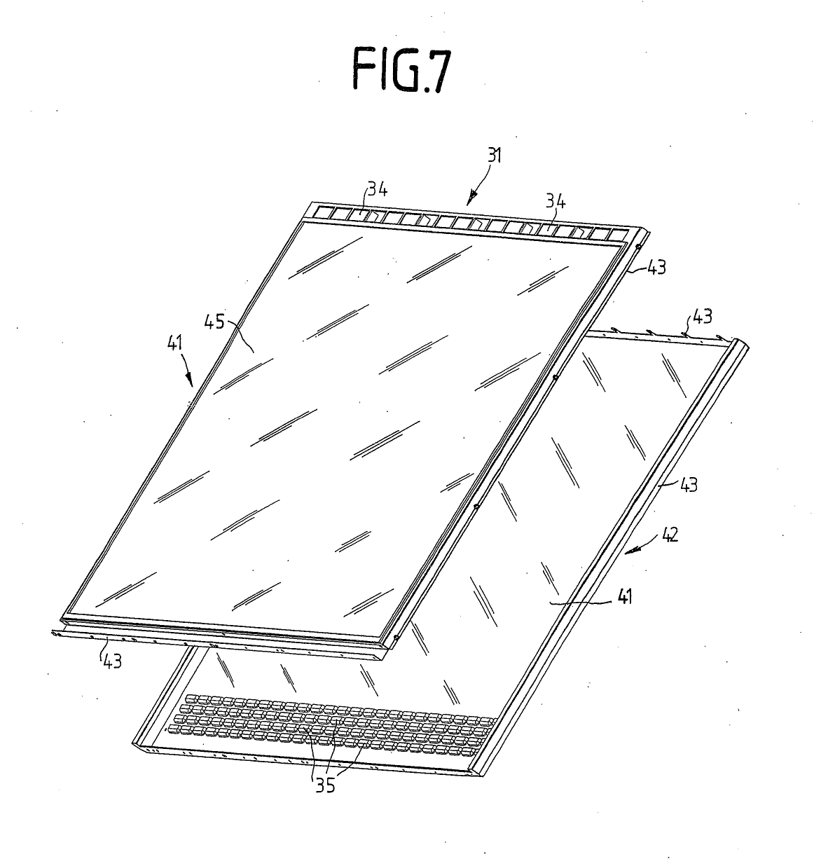

FIG. 7 shows an exploded illustration of the rear wall shown in FIG. 6,

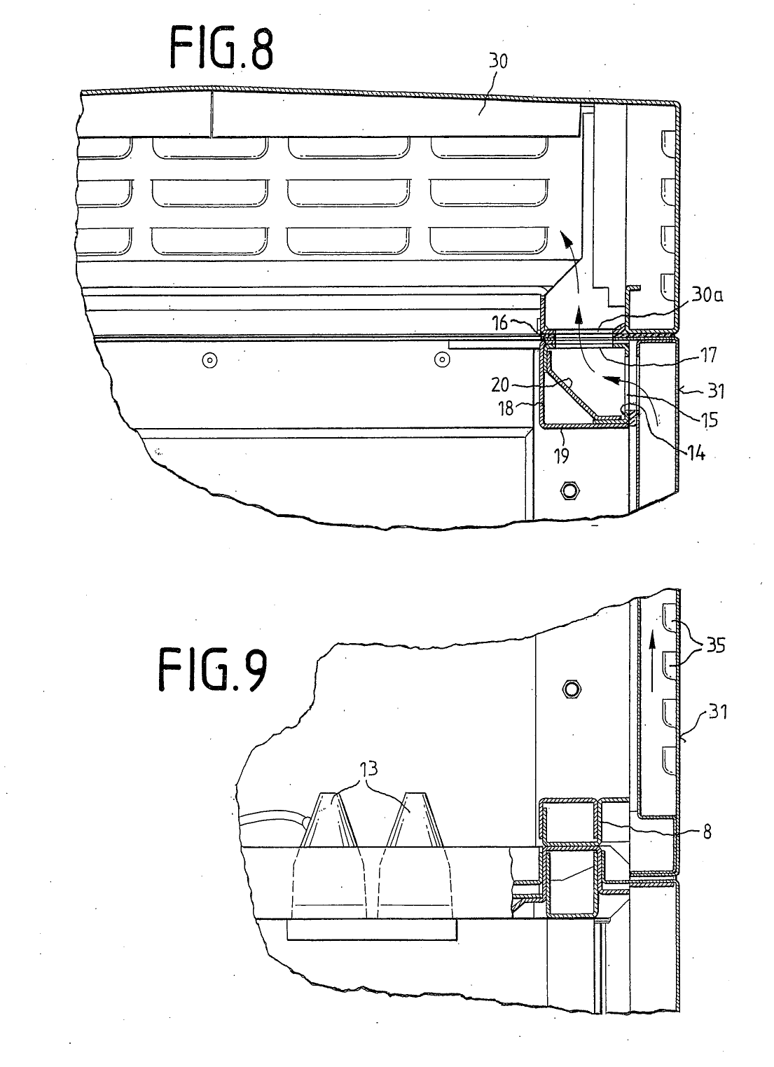

FIG. 8 shows a sectional illustration through the connecting part between the roof module and the door,

FIG. 9 shows a sectional illustration through the connecting part between the door and the base box,

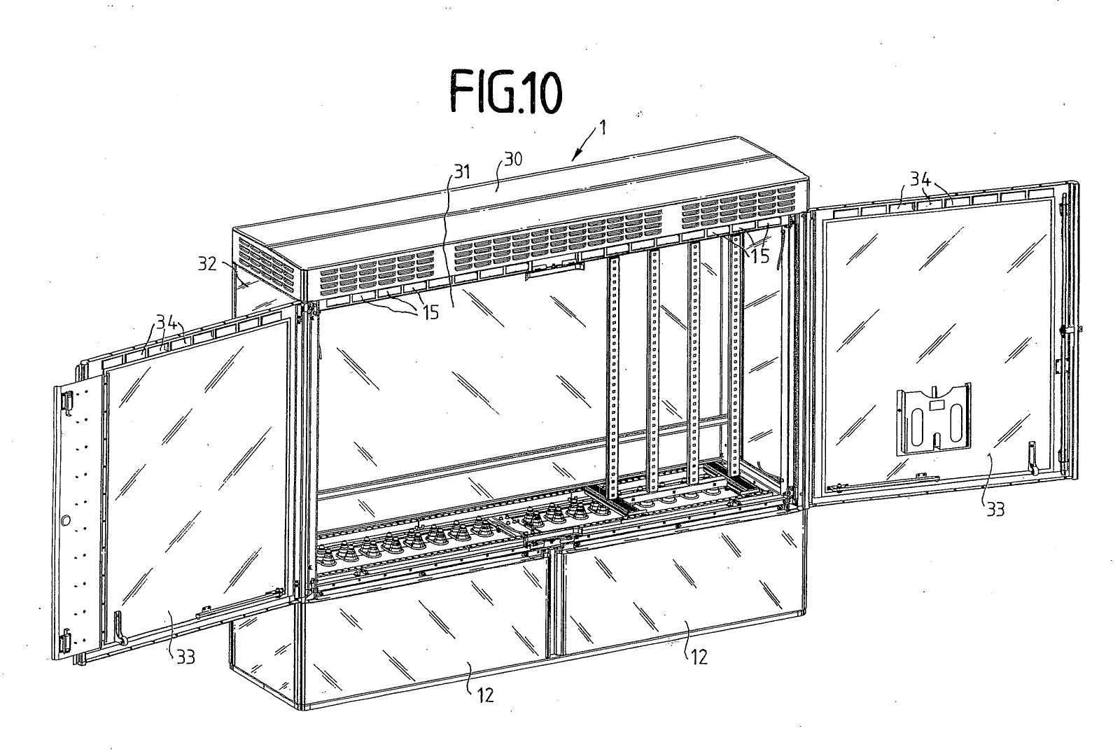

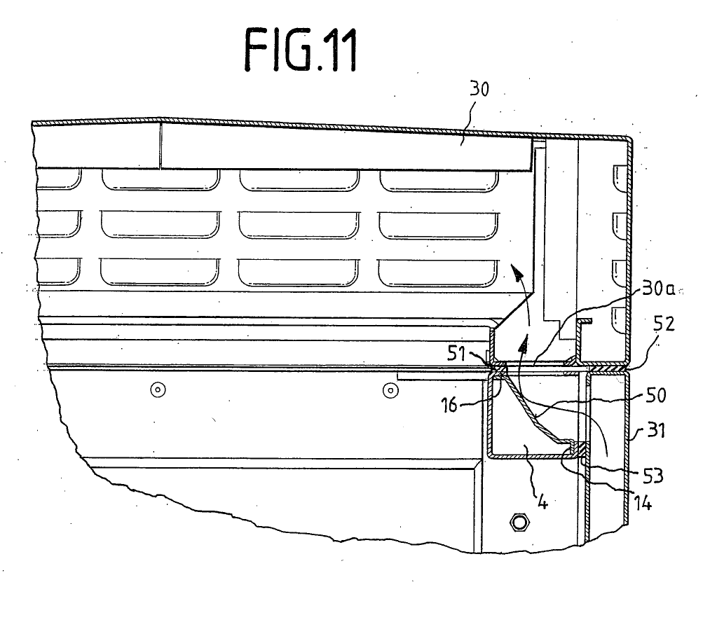

FIG. 10 shows a perspective illustration of the distribution cabinet with the doors open, and

FIG. 11 shows a schematic illustration of a cross section in terms of flow technology without holes.

FIG. 1 illustrates a distribution cabinet 1. The distribution cabinet 1 comprises a rack 2 with vertical struts 3, upper horizontal struts 4-7 and lower horizontal struts 8-11. The lower horizontal struts 8-11 are connected to two base boxes 12, on the upper side of which sealing elements 13 are arranged through which cores or cables can be passed from below into the interior of the distribution cabinet 1. The upper horizontal struts 4-7 are parallelepipedal, the outwardly pointing surface 14 having openings 15 and the upwardly pointing surface 16 having openings 17, the inwardly and downwardly pointing surfaces 18, 19 being entirely closed (see also FIG. 4). Furthermore, an air baffle 20 which is set at an angle is arranged in the upper horizontal struts 4-7 (see FIGS. 4 and 5).

As illustrated in FIG. 5 using the example of the strut 4, said strut comprises two elements 21, 22. The element 21 comprises the outwardly pointing surface 14 with openings 15 and the air baffle 20. A web 23, by means of which the element 21 is fastened on the downwardly pointing surface 19 of the element 22, is arranged between the surface 14 and the air baffle 20. A further web 24 is arranged on the air baffle 20 and is used to fasten the element 21 on the inwardly pointing surface 18 of the element 22. Webs 25, between which the openings 17 are then formed, are arranged on the upwardly aligned surface 16 of the element 22. Before the functions of the openings 15 and 17 or of the air baffle 20 are explained in more detail, the further configuration of the distribution cabinet 1 should first be explained with reference to FIGS. 2 and 3.

The distribution cabinet 1 furthermore comprises a roof module 30, a rear wall 31, two side walls 32 and two doors 33. The rear wall 31, the two side walls 32 and the two doors 33 are in this case each in the form of a double wall. In FIG. 3, openings 34 in the rear wall 31 are shown here which correspond, in the fitted state, to the openings 15 of the horizontal strut 4, i.e. are designed to be congruent with one another. Correspondingly, the side walls 32 and the doors 33 are also designed to have such openings, but these openings are not shown in the illustrations. Furthermore, the rear wall 31, the side walls 32 and the doors 33 have ventilation slots 35 (also referred to as gills), which are arranged in the region of the base box 12.

FIG. 6 shows the rear wall 31 in the assembled state and FIG. 7 shows the rear wall 31 in the exploded illustration. The rear wall 31 in this case comprises an inner element 41 and an outer element 42. The two elements 41, 42 are formed on the circumference with connecting elements 43. In the assembled state, in this case a channel is formed between the outer element 42 and the inner element 41, the wall 44 of the outer element 42 forming the outer wall 44 of the double wall, and the wall 45 of the inner element 41 forming the inner wall 45 of the double wall.

The way in which the openings 15, 17 of the strut 4 function will be explained with reference to FIGS. 8 and 9. Cold air enters the rear wall 31 via the ventilation slots 35 and flows upward in the direction of the arrow as a result of convection, heat being dissipated from the interior of the distribution cabinet 1 as the air flows past (see FIG. 9). The heated air rises upward and passes through the opening 34 of the rear wall and the opening 15 of the surface 14 of the strut 4 into said strut. The air flow is deflected upward on the air baffle 20 and passes through the opening 17 of the surface 16 of the strut 4 and an opening 30a, which corresponds to the opening 17, in the roof module 30 into the roof module, where the heat is then dissipated. In this case, a seal can be provided between the strut 4 and the rear wall 31. As a result of the fact that the air flow is guided horizontally into the strut 4, and only from there vertically upward into the roof module 30, openings impairing the sealtightness at the junction between the roof module 30 and the rear wall 31 can be dispensed with.

Finally, FIG. 10 illustrates the complete distribution cabinet 1, it being possible to see in addition the slope of the roof module which drops off toward the front.

FIG. 11 illustrates an upper horizontal strut 4 with a cross section in terms of flow technology without holes. The concave surface 50 in this case acts in the same way as the abovedescribed air baffle. Seals 51-53 are arranged in each case between the surface 16 and the roof module 30, the rear wall 31 and the roof module 30 and the surface 14 and the rear wall 31. Instead of the concave design, the surface may have a slope, for example.

### LIST OF REFERENCE Symbols

1 Distribution cabinet
2 Rack
3 Vertical struts
4-7 Upper horizontal struts
8-11 Lower horizontal struts
12 Base box
13 Sealing elements
14 Upwardly pointing surface
15 Openings
16 Upwardly pointing surface
18, 19 Downwardly pointing surfaces
20 Air baffle
21, 22 Elements
23, 24, 25 Webs
30 Roof module
30a Opening
31 Rear wall
32 Side walls
33 Doors
34 Openings
35 Ventilation slots
41 Inner element
42 Outer element
43 Connecting element
44 Outer wall
45 Inner wall
50 Concave surface
51-53 Seals

1. A distribution cabinet for communications and data technology, comprising a rack, at least one roof module, side walls, at least one rear wall and at least one door being fastened on the rack, the rack having vertical struts and lower and upper horizontal struts, the roof module being fastened on the upper horizontal struts, at least one side wall, a rear wall and/or a door being in the form of a double wall, an air flow being capable of flowing in the double wall, which air flow is flow-connected to an air flow in the roof module,
wherein
the upper horizontal strut on which the double wall is fastened has a cross section in terms of flow technology which allows for an at least partial horizontal air flow from the double wall and an at least partial vertical air flow to at least one opening in the roof module, the opening in the roof module being arranged so as to be offset inward with respect to the opening of the double wall.

2. The distribution cabinet as claimed in claim 1, wherein all of the upper horizontal struts are designed to have a cross section in terms of flow technology.

3. The distribution cabinet as claimed in claim 1, wherein the upper horizontal strut has openings, which are aligned toward the double wall and toward the roof module and correspond to the openings in the double wall and the roof module.

4. The distribution cabinet as claimed in claim 1, wherein the horizontal struts have a parallelepipedal basic shape, an air baffle set at an angle being arranged within the horizontal struts.

5. The distribution cabinet as claimed in claim 1, wherein the horizontal strut is formed in two parts.

6. The distribution cabinet as claimed in claim 1, wherein the outer or the inner wall of the double wall is designed to have ventilation slots.

7. The distribution cabinet as claimed in claim 1, wherein an intermediate wall is arranged between the outer and inner wall of the double wall, both the outer wall and the inner wall of the double wall being designed to have ventilation slots.

8. The distribution cabinet as claimed in claim 7, wherein the intermediate wall is in the form of a heat exchanger.
